(19) United States
(12) Patent Application Publication
(10) Pub. No.: US 2024/0134275 A1
(43) Pub. Date: Apr. 25, 2024

(54) ORGANOMETALLIC TIN CLUSTERS AS EUV PHOTORESIST

(71) Applicant: Feng Lu, Irvine, CA (US)

(72) Inventor: Feng Lu, Irvine, CA (US)

(21) Appl. No.: 18/371,789

(22) Filed: Sep. 22, 2023

Related U.S. Application Data
(60) Provisional application No. 63/412,061, filed on Sep. 30, 2022.

(51) Int. Cl. G03F 7/004; C07F 17/00

(52) U.S. Cl. CPC G03F 7/0044; C07F 17/00

(57) ABSTRACT

Organometallic tin clusters represented by chemical formulas [(C₅R₅Sn)₁₂O₁₄(OH)₆]X₂, [(C₅R₅Sn)₁₂O₁₄(OH)₄(L)₂]X₂, or [(C₅R₅Sn(O)O₂CR′]₆ and their uses as extreme ultraviolet (EUV) lithography photoresists are descried, wherein C₅R₅ comprises cyclopentadienyl C₅H₅ group, or substituted cyclopentadienyl C₅H₄R, C₅H₃R₂, C₅H₂R₃, C₅HR₄, or C₅R₅ group.

### CROSS PEFERENCE TO RELATED APPLICATIONS

This application claims priority to U.S. provisional patent application No. 63/412,061 filed on Sep. 30, 2022 to Lu, entitled “Organometallic tin clusters as EUV photoresist”, of which is entirely incorporated herein by reference.

### FIELD OF INVENTION

The present invention relates to organometallic (cyclopentadienyl)tin clusters as extreme ultraviolet (EUV) photoresists, and organometallic (cyclopentadienyl)tin compounds as precursors for preparation of (cyclopentadienyl)tin clusters.

### BACKGROUND OF THE INVENTION

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different solubility in developer solution between the exposed and non-exposed regions. The properties of EUV photoresist, such as resolution, sensitivity, line edge roughness (LER), line width roughness (LWR), etch resistance and ability to form thinner layer are important in photolithography.

Organometallic compounds have high EUV light adsorption because metals have high adsorption capacity of EUV radiation, and then can be used as photoresists and/or the precursors of metal oxides for photolithography at smaller level (e.g. <7 nm), which is of great interests for EUV radiation lithography. As promising advanced materials, organometallic (cyclopentadienyl)tin clusters (bearing π bond) can provide photoresist patterning with significant advantages, such as improved resolution, sensitivity, etch resistance, and lower line width/edge roughness without pattern collapse because of strong EUV radiation adsorption of tin, which have been demonstrated.

### SUMMARY OF THE INVENTION

In a first aspect, the present invention pertains to organometallic (cyclopentadienyl)tin clusters (bearing π bond) as EUV photoresists. The present invention is to provide the preparation and purification methodology of organometallic (cyclopentadienyl)tin clusters with high purity suitable for EUV lithography (e.g. <7 nm). The present invention is further to provide an alternative EUV photoresist with higher resolution, sensitivity, and lower line width roughness without pattern collapse during microelectronic patterning. The photosensitivity and thermostability of organometallic (cyclopentadienyl)tin clusters determine high resolution and efficiency of photoresist for EUV lithography.

In another aspect, the described organometallic (cyclopentadienyl)tin clusters comprise cyclopentadienyl (C₅H₅, or Cp), or substituted cyclopentadienyl C₅H₄R, C₅H₃R₂, C₅H₂R₃, C₅HR₄, and C₅R₅ units, wherein R is H, a substituted or unsubstituted alkyl, alkenyl, alkynyl, or cycloalkyl group with 1 to 20 carbon atoms, or substituted or unsubstituted aryl group with 6-20 carbon atoms, or an amino, cyano, ether, ester, halide, nitro, silyl, thiol, or carbonyl group, including but not limited to, a methyl, ethyl, isopropyl, tert-butyl, tert-amyl, sec-butyl, pentyl, hexyl, neopentyl, cyclohexyl, cyclopentyl, cyclobutyl, cyclopropyl, or phenyl group.

Cyclopentadienyl C₅R₅ group includes hapticity of η¹, η², η³, η⁴, or η⁵ of isomers. In some embodiments, cyclopentadienyl has η¹-, or η⁵- hapticity.

In a further aspect, the present disclosure pertains to organometallic (cyclopentadienyl)tin clusters, comprising [(C₅R₅Sn)₁₂O₁₄(OH)₆]X₂, [(C₅R₅Sn)₁₂O₁₄(OH)₄(L)₂]X₂, or [C₅R₅Sn(O)O₂CR′]₆, wherein R, R′ are independently H, linear or branched alkyl, alkenyl, alkynyl, or cycloalkyl group with 1 to 20 carbon atoms, or aryl group with 6-20 carbon atoms, including but not limited to, methyl, ethyl, isopropyl, tert-butyl, tert-amyl, sec-butyl, pentyl, hexyl, neopentyl, cyclohexyl, cyclopentyl, cyclobutyl, cyclopropyl, or phenyl group; X is anion, such as Cl⁻, or OH⁻; L is organic ligand, or solvent.

In other aspect, the invention pertains to the preparation of organometallic (cyclopentadienyl)tin clusters from organometallic (cyclopentadienyl)tin compounds as precursors represented by Chemical Formulas of FIGS. 1-30 through hydration, dehydration, controlled dehydration, condensation, or reaction with relevant reagents such as water, bases, organic acids, or other small organic molecules. For example, by dehydration and/or condensation of (cyclopentadienyl)stannoic acid (oxide hydroxide) represented by chemical formula (C₅R₅)SnOOH, controlled hydration of (cyclopentadienyl)tin trihalide represented by chemical formula (C₅R₅)SnX₃,(cyclopentadienyl)tin trialkoxide represented by chemical formula (C₅R₅)Sn(OR¹)(OR²)(OR³), (cyclopentadienyl)tin triamide represented by chemical formula (C₅R₅)Sn(N(R¹)₂)(N(R²)₂)(N(R³)₂), or (cyclopentadienyl)tin triester represented by chemical formula (C₅R₅)Sn(O—C(═O)R¹)(O—C(═O)R²)(O—C(═O)R³), wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group; wherein R¹, R², R³ are each independently H, a substituted or unsubstituted alkyl, alkenyl, alkynyl cycloalkyl, or cycloalkenyl group with 1 to 20 carbon atoms, or a substituted or unsubstituted aryl group with 6-20 carbon atoms; wherein X=F, Cl, Br, or I.

Furthermore, the present invention pertains to the methods for purification of organometallic (cyclopentadienyl)tin compounds and clusters. The purification methods include distillation, extraction, filtration, recrystallization, column chromatography, coordination and sublimation, or combinations thereof.

In a further aspect, a solution composition of organometallic (cyclopentadienyl)tin clusters EUV photoresist comprises one or more organometallic (cyclopentadienyl)tin clusters, solvents, and/or additives.

The solvents are organic solvents, and/or water. The organic solvents include, but not limited to, chloroform, dichloromethane, hexane, cyclohexane, tetrahydrofuran, dimethoxyethane, dimethylformamide, dimethyl sulfoxide, alcohols (e.g., methanol, ethanol, propanol, isopropanol, 1-butanol, 4-methyl-2-propanol, 4-methyl-2-pentenol), aromatic solvents (e.g., benzene, toluene, xylene), carboxylic acid, ethers (e.g., anisole, diethyl ether), esters (e.g., ethyl acetate, ethyl lactate, butyl acetate, propylene glycol monomethyl ether acetate), ketone (e.g., acetone, 2-heptanone, methyl ethyl ketone, acetone), or two or more mixtures thereof, and/ or the like, but is not limited thereto.

The invention pertains to organometallic (cyclopentadienyl)tin compounds represented by chemical formulas FIGS. 1-30, may also be used as photoresists for photolithography patterning, such as EUV photoresists.

The organometallic (cyclopentadienyl)tin clusters containing conjugated π bond have excellent (e.g., suitable) sensitivity to high energy light (e.g. EUV, X-ray, laser) due to tin strong absorption of extreme ultraviolet (EUV) at about 13.5 nm. Accordingly, organometallic (cyclopentadienyl)tin clusters may have improved sensitivity, resolution and stability, which are suitable for EUV photoresists, or as the precursors for EUV photoresists, compared with conventional organic, polymer, and/or inorganic photoresists.

The solution composition of highly pure radiation sensitive organometallic (cyclopentadienyl) tin clusters are suitable for EUV photoresists, or as the precursors for EUV photoresists.

### BRIEF DESCRIPTION OF THE DRAWINGS

FIGS. 1-30 are chemical formulas of organometallic (cyclopentadienyl)tin compounds, which may be used as the precursors for the preparation of organometallic (cyclopentadienyl)tin clusters, comprising (C₅R₅)₂SnX₂, (C₅R₅)₂Sn(OR¹)(R²), (C₅R₅)²Sn(OR¹)(OR²), (C₅R₅)₂Sn(O—C (═O)R¹)(R²), (C₅R₅)2Sn(O—C(═O)R¹)(OR²), (C₅R₅)₂Sn(O—C(═O)R¹)(O—C(═O)R²), [(C₅R₅)₂Sn](OR¹)(O)[(C₅R₅)₂Sn](OR²), [(C₅R₅)₂Sn]₂(O)₂, (C₅R₅)₂Sn(R¹)(N(R²)₂), (C₅R₅)₂Sn(N(R¹)₂)(N(R²)₂), (C₅R₅)SnX₃, (C₅R₅)SnO(OH), [(C₅R₅)SnO]₂O, (C₅R₅)SnO(OR¹), (C₅R₅)SnO(O—C(═O)R¹), (C₅R₅)Sn(R¹)(R²)(OR³), (C₅R₅)Sn(R¹)X₂, (C₅R₅)Sn(R¹)(R²)X, (C₅R₅)Sn(R¹)(OR²)(OR³), (C₅R₅)Sn(OR¹)(OR²)(OR³), (C₅R₅)Sn(O—C(═O)R¹)(OR²)(OR³), (C₅R₅)Sn(O—C(═O)R¹)(O—C(═O)R²)(OR³), (C₅R₅)Sn(O—C(═O)R¹)(O—C(═O)R²)(O—C(═O)R³), (C₅R₅)Sn(O—C(═O)R¹)(R²)(R³), (C₅R₅)Sn(O—C(═O)R¹)(O—C(═O)R²)(R³), [(C₅R₅)Sn(OR¹)](O)₂[(C₅R₅)Sn(OR²)], [(C₅R₅)Sn(R¹)](O)₂[(C₅R₅)Sn(R²)], (C₅R₅)Sn(R¹)(R²)(N(R³)₂), (C₅R₅)Sn(R¹)(N(R²)₂)(N(R³)₂), or (C₅R₅)Sn(N(R¹)₂)(N(R²)₂)(N(R³)₂); wherein C₅R₅ comprises cyclopentadiene C₅H₅, or substituted cyclopentadienyl C₅H₄R, C₅H₃R₂, C₅H₂R₃, C₅HR₄, or C₅R₅ group with the hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group, wherein R¹, R², R³ are each independently H, a substituted or unsubstituted alkyl, alkenyl, alkynyl cycloalkyl, or cycloalkenyl group with 1 to 20 carbon atoms, or a substituted or unsubstituted aryl group with 6-20 carbon atoms, X=F, Cl, Br, or I. The as-synthesized organometallic (cyclopentadienyl)tin clusters are suitable for EUV photoresists.

### DETAILED DESCRIPTION

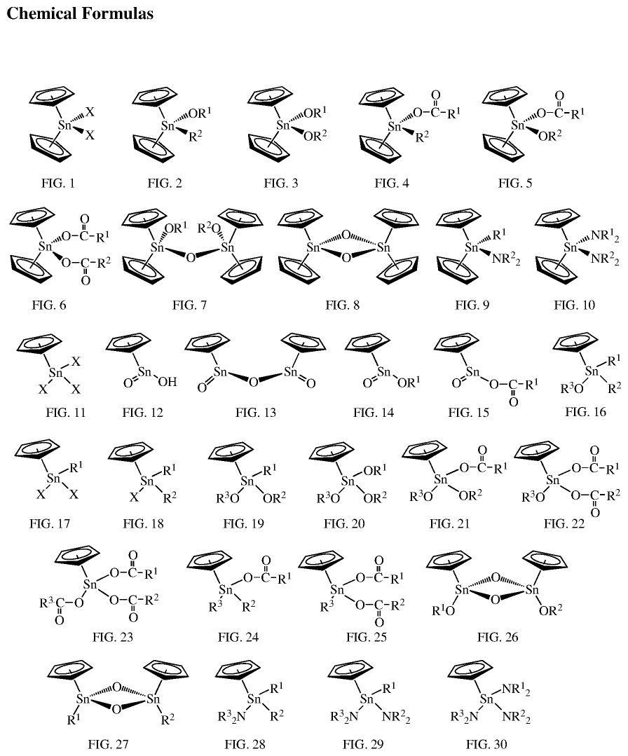

The present invention disclosure organometallic (cyclopentadienyl)tin clusters represented by chemical formulas [(C₅R₅Sn)₁₂O₁₄(OH)₆]X₂, [(C₅R₅Sn)₁₂O₁₄(OH)₄(L)₂]X₂, or [(C₅R₅Sn(O)O₂CR′]₆ as EUV photoresists, (cyclopentadienyl)tin compounds represented by chemical formulas of FIGS. 1-30 as precursors for the preparation of (cyclopentadienyl)tin clusters, and the preparation and purification methods with high purity for microelectronic EUV lithography patterning, wherein C₅R₅ comprises cyclopentadienyl (C₅H₅, or Cp), or substituted cyclopentadienyl C₅H₄R, C₅H₃R₂, C₅H₂R₃, C₅HR₄, and C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group; wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; wherein L is organic ligand or solvent. For example, methylcyclopentadienyl (C₅H₄Me, or MeCp), dimethylcyclopentadienyl (C₅H₃Me₂ or Me₂Cp), trimethylcyclopentaidenyl (C₅H₂Me₃, or Me₃Cp), tetramethylcyclopentadienyl (C₅HMe₄, or Me₄Cp), pentamethylcyclopentadienyl (C₅Me₅ or Cp*), or other alkyl/aryl substituted cyclopentadiene, including but not limited to ethyl, propyl, butyl, pentyl, hexyl, phenyl group. The as-synthesized organometallic (cyclopentadienyl)tin clusters are suitable for EUV photoresists, or as the precursors for EUV photoresists.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The term “alkyl” or “alkyl group” refers to a substituted or unsubstituted saturated linear or branched-chain hydrocarbon of 1 to 20 carbon atoms. The term “cycloalkyl” or “cycloalkyl group” refers to a substituted or unsubstituted cyclic hydrocarbon of 1 to 20 carbon atoms. The term “alkenyl” or “alkenyl group” refers to a substituted or unsubstituted unsaturated hydrocarbon containing C═C bond of 1 to 20 carbon atoms. The term “alkynyl” or “alkynyl group” refers to a substituted or unsubstituted unsaturated group C≡C containing hydrocarbon of 1 to 20 carbon atoms. The term “cycloalkenyl” or “cycloalkenyl” group refers to a substituted or unsubstituted C4 to C8 aliphatic unsaturated organic groups including at least one double bond. The term ‘aryl” refers to a substituted or unsubstituted aromatic group with 6-20 carbon atoms.

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

Organometallic photoresists are used in EUV lithography, because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance, pattern collapse and increase defects.

In general, metal central plays the key role in determining the absorption of photo radiation. Tin provides strong absorption of extreme ultraviolet (EUV) light at 13.5 nm, therein tin cations can be selected based on the desired radiation and absorption cross section. The organic ligand bonded to tin also has absorption of EUV light. The tuning and modification of organic ligands can change the sensitivity and radiation absorption, and the desired control of the material properties.

Organometallic tin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation (e.g., EUV) becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

Organometallic (cyclopentadienyl)tin clusters, represented by chemical formulas [(C₅R₅Sn)₁₂O₁₄(OH)₆]X₂, [(C₅R₅Sn)₁₂O₁₄(OH)₄(L)₂]X₂, or [(C₅R₅Sn(O)O₂CR′]₆, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group; wherein R′ is H, a substituted or unsubstituted alkyl, alkenyl, alkynyl cycloalkyl, or cycloalkenyl group with 1 to 20 carbon atoms, or a substituted or unsubstituted aryl group with 6-20 carbon atoms; X is anion, such as Cl⁻, or OH⁻; L is organic ligand, or solvent, which can be prepared from organometallic (cyclopentadienyl)tin compounds represented by chemical formulas of FIGS. 1-30 reacting with appropriate reagents under ambient conditions.

The cyclopentadienyl-Sn bond (Cp—Sn bond) is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (C₅R₅) group is much more sensitive to UV light compared with alkyl (e.g., methyl, butyl) groups under identical conditions. This property is beneficial to decrease EUV light dose and increase resolution.

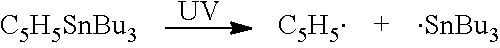

Cyclopentadienyl group (C₅R₅, or Cp) may impart photosensitivity to the compounds, and the Cp—Sn bond formed may promote suitable solubility in an organic solvent to the organometallic (cyclopentadienyl)tin compounds. Accordingly, these Cp—Sn bond containing organometallic (cyclopentadienyl)tin compounds according to an embodiment may have improved sensitivity, resolution and stability, and may suitable for EUV photoresists, and/or the precursors for EUV lithography to form tin oxide or tin oxide hydroxide film.

The organometallic (cyclopentadienyl)tin clusters contain cyclopentadienyl-Sn (Cp—Sn) bond and may have excellent (e.g., suitable) sensitivity to EUV radiation light due to the tin adsorption high energy EUV ray at 13.5 nm and the disruption of Cp—Sn bond to form free radical, tin oxide and relative products. Accordingly, the solution composition of organometallic (cyclopentadienyl)tin clusters as EUV photoresists may have improved or excellent sensitivity, resolution, stability, lower line edge and width roughness, compared with organic, polymer photoresist, or inorganic photoresist.

As one of ordinary skill in the art will recognize, the chemical compounds listed here are merely intended as illustrated examples of the organometallic (cyclopentadienyl)tin clusters, and are not intended to limit the embodiments to only those organometallic (cyclopentadienyl)tin clusters specifically described. Rather, any suitable organometallic (cyclopentadienyl)tin clusters may be used, and all such organometallic (cyclopentadienyl)tin clusters are fully intended to be included within the scope of the present embodiments.

The organometallic (cyclopentadienyl)tin compounds contain cyclopentadienyl group (bearing π bond). Cyclopentadienyl C₅R₅ group represents cyclopentadienyl C₅H₅ group, or substituted cyclopentadienyl C₅H₄R, C₅H₃R₂, C₅H₂R₃, C₅HR₄, or C₅R₅ group, R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group, including but not limited to, methyl, ethyl, propyl, n-butyl, t-butyl, hexyl, phenyl, or benzyl group.

In the present disclosure, the term “substituted” refers to replacement of a hydrogen atom with a C1 to C20 alkyl group, a C1to C20 alkenyl group, a C1 to C20 alkynyl group, a C1 to C20 cycloalkyl group, a C6 to C20 aryl group, or other relevant groups.

In an embodiment, the organometallic (cyclopentadienyl)tin compounds for preparation of organometallic (cyclopentadienyl)tin clusters according to embodiments of the present disclosure may be represented by at least one of examples from FIGS. 1-30. FIGS. 1-30 also represent the hapticity of η¹, η², η³, η⁴, or η⁵ with corresponding molecular structures of isomers.

Examples of specific organometallic (cyclopentadienyl)tin precursors for the synthesis of organometallic (cyclopentadienyl)tin clusters that may be used in implementations of the invention, including represented by Chemical Formulas of FIGS. 1-30, but not limited to, (C₅R₅)₂SnX₂, (C₅R₅)₂Sn(OR¹)(R²), (C₅R₅)₂Sn(OR¹)(OR²), (C₅R₅)₂Sn(O—C(═O)R¹)(R²), (C₅R₅)₂Sn(O—C (═O)R¹)(OR²), (C₅R₅)₂Sn(O—C(═O)R¹)(O—C(═O)R²), [(C₅R₅)₂Sn](OR¹)(O)[(C₅R₅)₂Sn](OR²), [(C₅R₅)₂Sn]₂(O)₂, (C₅R₅)₂Sn(R¹)(N(R²)₂), (C₅R₅)₂Sn(N(R¹)₂)(N(R²)₂), (C₅R₅)SnX₃, (C₅R₅)SnO(OH), [(C₅R₅)SnO]₂O, (C₅R₅)SnO(OR¹), (C₅R₅)SnO(O—C(═O)R¹), (C₅R₅)Sn(R¹)(R²)(OR³), (C₅R₅)Sn(R¹)X₂, (C₅R₅)Sn(R¹)(R²)X, (C₅R₅)Sn(R¹)(OR²)(OR³), (C₅R₅)Sn(OR¹)(OR²)(OR³), (C₅R₅)Sn(O—C(═O)R¹)(OR²)(OR³), (C₅R₅)Sn(O—C(═O)R¹)(O—C (═O)R²)(OR³), (C₅R₅)Sn(O—C(═O)R¹)(O—C(═O)R²)(O—C(═O)R³), (C₅R₅)Sn(O—C (═O)R¹)(R²)(R³), (C₅R₅)Sn(O—C(═O)R¹)(O—C(═O)R²)(R³), [(C₅R₅)Sn(OR¹)](O)₂[(C₅R₅)Sn(OR²)], [(C₅R₅)Sn(R¹)](O)₂[(C₅R₅)Sn(R²)], (C₅R₅)Sn(R¹)(R²)(N(R³)₂), (C₅R₅)Sn(R¹)(N(R²)₂)(N(R³)₂), or (C₅R₅)Sn(N(R¹)₂)(N(R²)₂)(N(R³₂); wherein C₅R₅ is cyclopentadienyl C₅H₅ group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group, wherein R¹, R², R ₃ are each independently H, a substituted or unsubstituted alkyl, alkenyl, alkynyl cycloalkyl, or cycloalkenyl group with 1 to 20 carbon atoms, or a substituted or unsubstituted aryl group with 6-20 carbon atoms, wherein X=F, Cl, Br, or I.

In some embodiments, organometallic tin-containing EUV photoresists overcome the disadvantages of current organic polymeric photoresist EUV lithography like very low throughput of wafers and poor adsorption of EUV.

The organometallic (cyclopentadienyl)tin clusters photoresist composition according to embodiments of the present disclosure may have relatively improved photosensitivity, sensitivity, resolution, and etch resistance, compared with related conventional organic, polymer, and/or inorganic resists, wherein cyclopentadienyl, or substituted cyclopentadienyl group, oxygen or various other groups are bonded to tin atom.

The organometallic (cyclopentadienyl)tin clusters EUV photoresist may have high sensitivity (low expose dose photoresist, e.g., <20 mJ/cm ²) and toughness; low or free pattern defectivity at nanoscale. The organometallic (cyclopentadienyl)tin clusters EUV photoresist may have tight pitch (e.g., <10 nm), and may sustain the yield and deliver high resolution.

The organometallic (cyclopentadienyl)tin clusters are soluble in appropriate organic solvents for further photolithography pattern processing. The solution of organometallic (cyclopentadienyl)tin clusters photoresist can be formed by dissolving the relevant organotin clusters in organic solvents, including but not limit to, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organometallic (cyclopentadienyl)tin clusters can be utilized as EUV photoresists for further processing and patterning. A person of ordinary skills in the art will recognize that the choice of solvents and solution composition components within the explicit ranges of above are contemplated and are within the present disclosure.

The solubility of organometallic (cyclopentadienyl)tin clusters in organic solvents, and/or water may be improved, and dissolution during an extreme ultraviolet (EUV) exposure.

Accordingly, a nanoscale pattern having improved sensitivity and limited resolution may be afforded by using of organometallic (cyclopentadienyl)tin clusters. Additionally, the as-formed pattern by using of organometallic (cyclopentadienyl)tin clusters may not collapse while having a high aspect ratio.

Examples of specific organometallic (cyclopentadienyl)tin clusters that may be used in implementations of the invention including [(C₅R₅Sn)₁₂O₁₄(OH)₆]X₂, [(C₅R₅Sn )₁₂O₁₄(OH)₄(L)₂]X₂, and [(C₅R₅Sn(O)O₂CR′]₆, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; wherein X is an anion; L is organic ligand, or solvent, such as methoxy (CH₃O—), or ethoxy (C₂H₅O—) group.

All chemical manipulations, including preparation and purification, are performed under an inert atmosphere of purified nitrogen or argon in dry and degassed solvents by employing standard Schlenk techniques. The methods for purification of organometallic (cyclopentadienyl)tin compounds represented by Chemical Formulas of FIGS. 1-30, or (cyclopentadienyl)tin clusters, comprise distillation, extraction, filtration, recrystallization, column chromatography, coordination, or sublimation, or combinations thereof.

In some embodiments, the reactions of (cyclopentadienyl)tin compound (cyclopentadienyl)stannoic acid represented by chemical formula of (C₅H₅)SnOOH, (cyclopentadienyl)tin trihalide represented by chemical formula of (C₅H₅)SnX₃ (X=F, Cl, Br, or I), (cyclopentadienyl)tin trialkoxide represented by chemical formula of (C₅R₅)Sn(OR¹)(OR²)(OR³), (cyclopentadienyl)tin triamide represented by chemical formula of (C₅R₅)Sn(N(R¹)₂)(N(R²)₂)(N(R³)₂), or (cyclopentadienyl)tin triester represented by chemical formula of (C₅R₅)Sn(O—C(═O)R¹)(O—C(═O)R²)(O—C(═O)R³), with water, base (e.g., ammonium hydroxide NH₄OH, sodium hydroxide NaOH, potassium hydroxide KOH), or organic acid (e.g., acetic acid, formic acid, citric acid), produce organometallic tin clusters [(C₅R₅Sn)₁₂O₁₄(OH)₆]X₂, [(C₅R₅Sn)₁₂O₁₄(OH)₄(L)₂]X₂, or [(C₅R₅Sn(O)O₂CR′]₆.

In some embodiments, the hydrolysis of (C₅R₅)SnX₃ in base solution, including but not limited to, ammonium hydroxide, sodium hydroxide, potassium hydroxide under ambient condition, produces organometallic (cyclopentadienyl)tin clusters, such as [(C₅R₅Sn)₁₂O₁₄(OH)₆]X₂ cluster, which are suitable for EUV photoresist, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group. A person of ordinary skills in the art will recognize that additional bases and reaction conditions within the explicit ranges of above are contemplated and are within the present disclosure.

In some embodiments, the hydrolysis of (cyclopentadienyl)tin trialkoxide, or (cyclopentadienyl)tin triamide, in water or alcohol under ambient condition produces organometallic (cyclopentadienyl)tin clusters, such as [(C₅R₅Sn)₁₂O₁₄(OH)₆](OH)₂, which are suitable for EUV photoresist, wherein R, R′ are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms. A person of ordinary skills in the art will recognize that additional solvents and reaction conditions within the explicit ranges of above are contemplated and are within the present disclosure.

In some embodiments, the reactions of (cyclopentadienyl)tin trihalide, (cyclopentadienyl)tin trialkoxide, or (cyclopentadienyl)tin triamide with organic acids (e.g., acetic acid) in organic solvents (e.g., alcohol), result in organometallic (cyclopentadienyl)tin clusters, such as [(C₅R₅Sn(O)O₂CR′]₆, which are suitable for EUV photoresist, wherein R, R′ are each independently H, a substituted or unsubstituted alkyl, alkenyl, alkynyl, or cycloalkyl group with 1 to 20 carbon atoms, or a substituted or unsubstituted aryl group with 6-20 carbon atoms. A person of ordinary skills in the art will recognize that additional organic acids and reaction conditions within the explicit ranges of above are contemplated and are within the present disclosure.

In some embodiments, the condensation reactions of (cyclopentadienyl)tin oxide hydroxide (C₅R₅)SnO(OH) with organic acids under ambient conditions, such as, but not limited to, formic acid, acetic acid, citric acid, propionic acid, isovaleric acid, butyric acid, valeric acid, caproic acid, glycolic acid, lactic acid, oxalic acid, or succinic acid, produce organometallic (cyclopentadienyl)tin clusters [(C₅R₅Sn(O)O₂CR′]₆, which are suitable for EUV photoresist, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms. A person of ordinary skills in the art will recognize that additional organic acids and reaction conditions within the explicit ranges of above are contemplated and are within the present disclosure.

In some embodiments, the reactions of organotin cluster [(C₅R₅)₁₂O₁₄(OH)₆]X₂ with organic acids (R′COOH) such as acetic acid result in drum-like organotin cluster [(C₅R₅Sn(O)O₂CR′]6 in organic solvent like dichloromethane.

In some embodiments, the reaction of bis(cyclopentadienyl)tin oxide (C₅R₅)SnO with organic acid (R′COOH) produces organotin clusters [(C₅R₅Sn(O)O₂CR′]6 in organic solvent such as toluene under ambient conditions like refluxing.

The molecular structures of organometallic (cyclopentadienyl)tin clusters [(CₚSn)₁₂O₁₄(OH)₆]X₂, [CₚSn(O)O₂CR′]₆ of the present disclosure are depicted as below (Cₚ═C₅R₅):

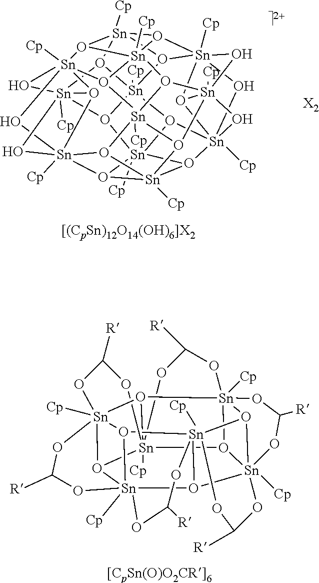

In some embodiments, organometallic (cyclopentadienyl)tin clusters impurities may result in contamination and defect for EUV photolithography. In some embodiments, the impurities can be the mixtures of other unseparated reactants, or side-products.

In one or more embodiments, the semiconductor EUV photoresists composition according to an embodiment may include one or more organometallic (cyclopentadienyl)tin clusters, a solvent, and/or an additive.

In general, the organic solvents selection can be determined by solubility, boiling point, reactivity, volatility, viscosity, flammability, and toxicity. The potential hydration and/or condensation may occur after organometallic tin compounds photoresists dissolve in organic solvent, and the characters of the species may change as a result of partial hydration and condensation, especially during the coating process. When the composition of the solution is references herein, the reference is to the component as added to the solution, since complex formulation may produce metal polynuclear species, and/or metal-containing nanoclusters in solution that may not be well characterized.

The solvent of the organometallic (cyclopentadienyl)tin clusters EUV photoresists composition according to the embodiment may be an organic solvent, and in some embodiments, may include, chloroform, dichloromethane, hexane, cyclohexane, tetrahydrofuran, dimethoxyethane, dimethylformamide, dimethyl sulfoxide, alcohols (e.g., methanol, ethanol, propanol, butanol, 4-methyl-2-propanol, 4-methyl-2-pentenol), aromatic solvents (e.g., benzene, toluene, xylene), carboxylic acid, ethers (e.g. diethyl ether, anisole), esters (e.g., ethyl acetate, ethyl lactate, butyl acetate, propylene glycol monomethyl ether acetate), ketone (e.g., acetone, 2-heptanone, 4-methyl-2-pentanone, methyl ethyl ketone), or combinations thereof, and/or the like, but is not limited thereto.

In some embodiments, the solvent to dissolve the organometallic (cyclopentadienyl)tin clusters EUV photoresist for coating can be different from the solvent as developer.

In some embodiments, the organometallic (cyclopentadienyl)tin clusters EUV photoresist composition may also contain an additive.

In some embodiments, the additive can be used to purify the impurities of trace metals or metallic complexes by-products. In some embodiments, the additive can be used to stabilize the photoresist composition and extend the storing time. In some embodiments, the additives consist of molecular chelating agents, including but not limited to phosphine ligand, amines, polyamines, alcohol amines, amino acids, biomolecules, e.g., ethylenediamine-tetra acetic acid (EDTA), chitosan, cellulose, glycol, but not limited to.

In some embodiments, the additive can be a resin. The resin may be organic polymer, or small organic aromatic molecules. In some embodiments, the additive can be a surfactant, such as tetra-octylammonium bromide, but not limited to.

In some embodiments, the additive can be a water adsorbent, such as glycol, but not limited to. In some embodiments, the additive can be an adhesion additive, such as a silane, but not limited to.

In some embodiments, the additive can be a protective polymer, such as a fluorinated polymer, but not limited to. In some embodiments, the additive can be an organic thiol, such as 1-dodecanethiol, but not limited to.

When organometallic (cyclopentadienyl)tin clusters photoresist exposes to extreme ultraviolet (EUV) radiation, the organometallic (cyclopentadienyl)tin clusters absorbs the EUV radiation, cyclopentadienyl ligand, and/or one or more R¹, R², R₃ group are cleaved from organometallic (cyclopentadienyl)tin clusters to form tin oxide or tin oxide hydroxide pattern. In some embodiments, the unexposed area of the substrate surface may be removed by the developer.

In some embodiments, the developer compositions for as-formed patters can be any suitable organic solvent, or aqueous solution, at low to high concentrations. In some embodiments, non-limiting examples of the organic solvent used in the method of forming patterns, the organic solvent can be one or more selected from, but not limited to, for example, chloroform, dichloromethane, hexane, cyclohexane, tetrahydrofuran, dimethoxyethane, dimethylformamide, dimethyl sulfoxide, ethyl lactate, n-butyl acetate, dioxane, ketones (e.g., acetone, 2-heptanone, methylethylketone, cyclohexanone, γ-butyrolactone, and/or the like), alcohols (e.g., methanol, ethanol, 1-propanol, isopropanol, 1-butanol, 4-methyl-2-propanol, 1-ethoxy-2-propanol, methyl isobutyl carbinol, and/or the like), carboxylic acid, ethers (e.g., anisole, diethyl ether, propylene glycol monomethyl ether, and/or the like), esters (e.g., ethyl acetate, n-butyl acetate, butyrolactone, propylene glycol monomethyl ester acetate, and/or the like), aromatic solvents (e.g., benzene, toluene, xylene, and/or the like), or combinations thereof.

In addition, the organometallic (cyclopentadienyl)tin clusters photoresist pattern according to an embodiment is not necessarily limited to the negative tone image, but may be formed to have a positive tone image. The developer determines the image types.

One or more examples embodiments of the present disclosure provide a semiconductor EUV photoresist composition according to an embodiment as hereinafter described.

The solution composition of (cyclopentadienyl)tin cluster photoresists can be utilized for photolithography patterning including extreme ultraviolet radiation (EUV), deep ultraviolet radiation (DUV), e-beam radiation, X-ray radiation, or ion-beam radiation for further processing and patterning.

Hereinafter, the present invention is described in more details through Examples regarding to the preparation of the organometallic (cyclopentadienyl)tin clusters EUV photoresist of the present embodiments. However, the present invention is not limited by the Examples. The following examples are provided for further illustration of certain embodiments of the disclosure, which is not necessarily limited to these embodiments.

### EXAMPLE

### Example 1

Synthesis of (cyclopentadienyl)tin trichloride. Under dried dinitrogen atmosphere, the solution of (cyclopentadienyl)sodium (C₅H₅Na) in THF was added dropwise to the solution of equivalent SnCl₄ in hexane (Caution: SnCl₄ is extremely hydrolytic when exposure to air or water and releasing HCl gaseous !!!) at −78° C. in hours with vigorously stirring. After addition, the mixture was slowly warmed to room temperature and stirred at room temperature for hours. After removal of all the volatiles, the residue was extracted by hexane and filtered through Celite. The filtration was evaporated in vacuum to result in (C₅H₅)SnCl₃ as yellow oil.

### Example 2

Synthesis of [(C₅H₅)Sn]₁₂O₁₄(OH)₆]Cl₂. Under N₂ atmosphere, in a 250 ml Schlenk bottle, (cyclopentadienyl)tin trichloride (C₅H₅)SnCl₃ (2.9 g, 10 mmol) and water (30 mL) were introduced. Aqueous KOH solution (5 ml, 1M) was then added dropwise over 1 h with vigorously stirring until the pH of the solution reached 4.0. Then the obtained suspension was stirred at room temperature overnight. The precipitate was filtered and washed with DI water (3×10 ml), then dried in vacuum. The obtained solid was purified by recrystallization from acetone at low temperature to result in analytically pure product. Yield: 1.06 g, 49%. ¹H NMR (298 K, 400.13 MHz, CDCl₃) δ=5.90 (m, 30 H), 5.53 (m, 30 H). MS (ES): m/z 2602.2 (M⁺). Elemental analysis of C₆₀H₆₆Sn₁₂O₂₀Cl₂(2602.02), anal. calculated C: 27.69 , H: 2.54; found C: 27.86, H, 2.92.

### Example ₃

Synthesis of [(C₅H₅)Sn(O)O₂CCH₃]₆. Under N₂ atmosphere, acetic acid (0.27 ml, 4.6 mmol) was added to the solution of (cyclopentadienyl)stannoic acid (C₅H₅)SnO(OH) (1 g, 4.6 mmol) in toluene (50 ml) in a Dean-Stark apparatus. The mixture was then refluxed with vigorously stirring for hours to remove the formed water. After cooling down to room temperature, all the volatiles were removed in vacuum. The residue was extracted by toluene and filed through Celite, and then evaporated the solvent to give the product [(C₅H₅)Sn(O)O₂CCH₃]₆. The recrystallization was conducted by slowly cooling down the hot toluene solution to 8° C. Yield: 630 mg, 53%. ¹H NMR (298 K, 400.13 MHz, CDCl₃) δ=5.81 (m, 30 H), 2.13 (s, 18 H). MS (ES): m/z 1553.1 (M⁺).

It is understood that the above-described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organometallic tin cluster photoresist composition, comprising a (cyclopentadienyl)tin cluster and a solvent,
wherein the (cyclopentadienyl)tin cluster comprising [(C₅R₅Sn)₁₂O₁₄(OH)₆]X₂, [(C₅R₅Sn)₁₂O₁₄(OH)₄(L)₂]X₂, or [(C₅R₅Sn(O)O₂CR′]₆,
wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group;
wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; wherein X is an anion; L is organic ligand, or solvent.

2. The organometallic tin cluster photoresist composition of claim 1, wherein C₅R₅ group comprises cyclopentadienyl C₅H₅ group, or substituted cyclopentadienyl C₅H₄R, C₅H₃R₂, C₅H₂R₃, C₅HR₄, or C₅R₅ group.

3. The organometallic tin cluster photoresist composition of claim 2, wherein C₅R₅ group comprises hapticity of η¹, η², η³, η⁴, or η⁵ of cyclopentadienyl isomers.

4. The organometallic tin cluster photoresist composition of 1, wherein cycloalkenyl group comprises substituted or unsubstituted C4 to C8 aliphatic unsaturated organic groups including at least one double bond.

5. The organometallic tin cluster photoresist composition of claim 1, wherein X is Cl⁻, or OH⁻anion, L is CH₃O group.

6. The organometallic tin cluster photoresist composition of claim 1, wherein R is H, a methyl, ethyl, propyl, n-butyl, or t-butyl group, R′ is H, a methyl, ethyl, propyl, n-butyl, or t-butyl group.

7. The organometallic tin cluster photoresist composition of claim 1, wherein R is H, R′ is methyl group.

8. A method of forming organometallic tin clusters, comprising:
reacting an organometallic (cyclopentadienyl)tin compound with a reagent,
wherein the organometallic (cyclopentadienyl)tin compound is one or more selected from the group chemical formulas consisting of:
(C₅R₅)₂SnX₂, (C₅R₅)₂Sn(OR¹)(R²), (C₅R₅)₂Sn(OR¹)(OR²), (C₅R₅)₂Sn(O—C(═O)R¹)(R²), (C₅R₅)₂Sn(O—C(═O)R¹)(OR²), (C₅R₅)₂Sn(O—C(═O)R¹)(O—C(═O)R²), [(C₅R₅)₂Sn](OR¹)(O)[(C₅R₅)₂Sn](OR²), [(C₅R₅)₂Sn]₂(O)₂, (C₅R₅)₂Sn(R¹)(N(R²)₂), (C₅R₅)₂Sn(N(R¹)₂)(N(R²)₂), (C₅R₅)SnX₃, (C₅R₅)SnO(OH), [(C₅R₅)SnO]₂, (C₅R₅)SnO(OR¹), (C₅R₅)SnO(O—C(═O)R¹), (C₅R₅)Sn(R¹)(R²)(OR³), (C₅R₅)Sn(R¹)X₂, (C₅R₅)Sn(R¹)(R²)X, (C₅R₅)Sn(R¹)(OR²)(OR³), (C₅R₅)Sn(OR¹)(OR²)(OR³), (C₅R₅)Sn(O—C(═O)R¹)(OR²)(OR³), (C₅R₅)Sn(O—C(═O)R¹)(O—C(═O)R²)(OR³), (C₅R₅)Sn(O—C(═O)R¹)(O—C(═O)R²)(O—C(═O)R³), (C₅R₅)Sn(O—C(═O)R¹)(R²)(R³), (C₅R₅)Sn(O—C(═O)R¹)(O—C(═O)R²)(R³), [(C₅R₅)Sn(OR¹)](O)₂[(C₅R₅)Sn(OR²)], [(C₅R₅)Sn(R¹)](O)₂[(C₅R₅)Sn(R²)], (C₅R₅)Sn(R¹)(R²)(N(R³)₂), (C₅R₅)Sn(R¹)(N(R²)₂)(N(R³)₂), or (C₅R₅)Sn(N(R¹)₂)(N(R²)₂)(N(R³)₂);
wherein C₅R₅ is cyclopentadienyl C₅H₅ group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group;
wherein R¹, R², R ³ are each independently H, a substituted or unsubstituted alkyl, alkenyl, alkynyl cycloalkyl, or cycloalkenyl group with 1 to 20 carbon atoms, or a substituted or unsubstituted aryl group with 6-20 carbon atoms; X=F, Cl, Br, or I.

9. The method of forming organometallic tin clusters of claim 8, wherein the organometallic tin cluster comprises [(C₅R₅Sn)₁₂O₁₄(OH)₆]X₂, [(C₅R₅S n)₁₂O₁₄(OH)₄(L)₂]X₂, or [(C₅R₅Sn(O)O₂CR′]₆.

10. The method of forming organometallic tin clusters of claim 8, wherein the reagent includes water, base, organic acid, or combinations thereof.

11. The method of forming organometallic tin clusters of claim 10, wherein the base includes ammonium hydroxide, sodium hydroxide, or potassium hydroxide.

12. The method of forming organometallic tin clusters of claim 10, wherein the organic acid includes formic acid, acetic acid, citric acid, propionic acid, isovaleric acid, butyric acid, valeric acid, caproic acid, glycolic acid, lactic acid, oxalic acid, or succinic acid.

13. The method of forming organometallic tin clusters of claim 8, wherein the organometallic (cyclopentadienyl)tin compounds may also be used as photoresists.

14. The method of forming organometallic tin clusters of claim 8, wherein R is H, a methyl, ethyl, propyl, n-butyl, or t-butyl group, R¹, R², R ³ are each independently a methyl, ethyl, isopropyl, tert-butyl, tert-amyl, sec-butyl, pentyl, hexyl, neopentyl, cyclohexyl, cyclopentyl, cyclobutyl, cyclopropyl, cyclopentadienyl, phenyl, or benzyl group.

15. The method of forming organometallic tin clusters of claim 9, wherein the organometallic tin clusters comprise [(C₅H₅Sn)₁₂O₁₄(OH)₆]Cl₂, [(C₅H₅Sn)₁₂O₁₄(OH)₆](OH)₂, [(C₅H₅Sn)₁₂O₁₄(OH)₄(OCH₃)₂]Cl₂, or [(C₅H₅Sn(O)O₂CCH₃]₆.

16. An organometallic tin cluster EUV photoresist composition, comprising: a (cyclopentadienyl)tin cluster, a solvent, and/or an additive;
wherein the (cyclopentadienyl)tin cluster comprising [(C₅R₅Sn)₁₂O₁₄(OH)₆]X₂, [(C₅R₅Sn)₁₂O₁₄(OH)₄(L)₂]X₂, or [(C₅R₅Sn(O)O₂CR′]₆,
wherein R is H, an alkyl, alkenyl, alkynyl, cycloalkyl, or cycloalkenyl group with 1 to 20 carbon atoms, or an aryl group with 6-20 carbon atoms; R′ is H, an alkyl, alkenyl, alkynyl, cycloalkyl, or cycloalkenyl group with 1 to 20 carbon atoms, or an aryl group with 6-20 carbon atoms; X is an anion; L is alkoxy ligand.

17. The organometallic tin cluster EUV photoresist composition of claim 16, wherein C₅R₅ comprises cyclopentadienyl C₅H₅, or substituted cyclopentadienyl C₅H4R, C₅H₃R₂, C₅H₂R₃, C₅HR₄, or C₅R₅ group.

18. The organometallic tin cluster EUV photoresist composition of claim 17, wherein R is H, a methyl, ethyl, propyl, n-butyl, t-butyl, phenyl, or benzyl group.

19. The organometallic tin cluster EUV photoresist composition of claim 16, wherein (cyclopentadienyl)tin clusters comprise [(C₅H₅Sn)₁₂O₁₄(OH)₆]Cl₂, [(C₅H₅Sn)₁₂O₁₄(OH)₆](OH)₂, [(C₅H₅Sn)₁₂O₁₄(OH)₄(OCH₃)₂]Cl₂, or [(C₅H₅Sn(O)O₂CCH₃]₆.

20. The organometallic tin cluster EUV photoresist composition of claim 16, wherein the solvent comprises methanol, ethanol, benzene, toluene, xylene, or combinations thereof.
